(19) United States
(12) Patent Application Publication
(10) Pub. No.: US 2008/0191701 A1
(43) Pub. Date: Aug. 14, 2008

(54) Method and Apparatus for Inspecting Light-Emitting Element and Method and Apparatus for Burn-In

(75) Inventor: Takeshi YAJIMA, Suwa-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/024,436

(22) Filed: Feb. 1, 2008

(30) Foreign Application Priority Data
Feb. 13, 2007 (JP) 2007-032060
Jan. 22, 2008 (JP) 2008-011412

(51) Int. Cl. G01R 31/44

(52) U.S. Cl. 324/414

(57) ABSTRACT

A method for inspecting a light-emitting element for a defect includes (a) measuring a light output of a light-emitting element while injecting a current into the light-emitting element, (b) setting a drive current according to an injected current and a measured light output, (c) measuring a light output while injecting the set drive current into the light-emitting element in a forward direction, and (d) determining whether or not the light-emitting element has a defect, according to the light output measured in step (c).

The entire disclosure of Japanese Patent Application Nos: 2007-032060, filed Feb. 13, 2007 and 2008-11412, filed Jan. 22, 2008 is expressly incorporated by reference herein.

### BACKGROUND

1. Technical Field

The present invention relates to a method and an apparatus for inspecting a light-emitting element and a method and an apparatus for burn-in.

2. Related Art

Light-emitting elements such as surface-emitting semiconductor lasers are drawing attention in recent years. Such light-emitting elements are generally manufactured by growing multiple semiconductor layers each having a crystal structure. Extremely complicated processes are performed to manufacture such light-emitting elements. Defects may occur in light-emitting elements during the crystal growth process, or minute cracks may occur therein due to mechanical stress or a shock. To address this problem, screening methods have been developed for identifying light-emitting elements having such defects or the like. For example, JP-A-2005-500691 discloses a method for identifying defective light-emitting elements. In JP-A-2005-500691, a test is conducted in an atmosphere at 85 to 150° C. while providing a direct current of 5 to 20 mA as a drive current. However, such a method presents problems such as failing to sort out a light-emitting element that includes a defect but does not obviously show degradation in characteristic due to the defect.

### SUMMARY

An advantage of the invention is to provide a method and an apparatus for inspecting a light-emitting element that each improves the inspection accuracy as well as a method and an apparatus for burn-in that each efficiently eliminates initial changes in light output of a light-emitting element.

According to a first aspect of the invention, a method for inspecting a light-emitting element for a defect includes (a) measuring a light output of a light-emitting element while injecting a current into the light-emitting element, (b) setting a drive current according to an injected current and a measured light output, (c) measuring a light output while injecting the set drive current into the light-emitting element in a forward direction, and (d) determining whether or not the light-emitting element has a defect, according to the light output measured in step (c).

According to the method for inspecting a light-emitting element according to the first aspect of the invention, a defect is detected using the drive current suitable for the light-emitting element. As a result, the ability to detect a defect is significantly improved. Also, such detection is performed in a short time. This prevents a reduction in life of the light-emitting element 10 due to undergoing an inspection.

In the method for inspecting a light-emitting element according to the first aspect of the invention, in step (b), a current-light output characteristic of the light-emitting element may be obtained according to an injected current and a measured light output, and a drive current is set using the current-light output characteristic.

The method for inspecting a light-emitting element according to the first aspect of the invention may further include putting a light-emitting element under a predetermined temperature environment between steps (b) and (c).

In the method for inspecting a light-emitting element according to the first aspect of the invention, the predetermined temperature may be a room temperature.

In the method for inspecting a light-emitting element according to the first aspect of the invention, in step (b), a drive current may be set according to a current at which a measured light output is a maximum value.

In the method for inspecting a light-emitting element according to the first aspect of the invention, in step (b), a current equal to or larger than a current at which a measured light output is a maximum value and equal to or smaller than a current at which a measured light output is 70% of the maximum value may be set as a drive current.

In the method for inspecting a light-emitting element according to the first aspect of the invention, in step (c), at least an initial value of the light output and a light output after a lapse of a predetermined time from start of injection of the drive current may be measured. In step (d), if a rate of change of the light output after the lapse of the predetermined time with respect to the initial value is equal to or larger than a predetermined value, it may be determined that the light-emitting element has a defect.

According to a second aspect of the invention, a method for inspecting a light-emitting element for a defect includes (a) measuring a light output of a light-emitting element while injecting a current into the light-emitting element, (b) setting a drive current according to an injected current and a measured light output, (c) measuring an inter-terminal voltage while injecting the set drive current into the light-emitting element in a forward direction, and (d) determining whether or not the light-emitting element has a defect, according to the inter-terminal voltage.

In the method for inspecting a light-emitting element according to the second aspect of the invention, in step (c), at least an initial value of the inter-terminal voltage and an inter-terminal voltage after a lapse of a predetermined time from start of injection of the drive current may be measured. In step (d), if a rate of change of the inter-terminal voltage after the lapse of the predetermined time with respect to the initial value is equal to or larger than a predetermined value, it may be determined that the light-emitting element has a defect.

According to a third aspect of the invention, a inspection apparatus for inspecting a light-emitting element for a defect includes a current injection unit for injecting a current into a light-emitting element, a light output measurement unit for measuring a light output of the light-emitting element, and a drive current setting unit for setting a drive current according to an injected current and a measured light output, and a defect determination unit for determining whether or not the light-emitting element has a defect, according to a measured value of a light output at a time when the set drive current is injected into the light-emitting element.

In the apparatus for inspecting a light-emitting element according to the third aspect of the invention, the drive current setting unit may obtain a current-light output characteristic of the light-emitting element according to an injected current and a measured light output, and may set a drive current using the current-light output characteristic.

In the apparatus for inspecting a light-emitting element according to the third aspect of the invention, the drive current setting unit may set a drive current according to a current at which a measured light output is a maximum value.

In the apparatus for inspecting a light-emitting element according to the third aspect of the invention, the drive current setting unit may set, as a drive current, a current equal to or larger than a current at which a light output measured by the light output measurement unit is a maximum value and equal to or smaller than a current at which a light output measured by the light output measurement unit is 70% of the maximum value.

According to a fourth aspect of the invention, an inspection apparatus for inspecting a light-emitting element for a defect includes a current injection unit for injecting a current into a light-emitting element, a light output measurement unit for measuring a light output of the light-emitting element, and a drive current setting unit for setting a drive current according to an injected current and a measured light output, and a defect determination unit for determining whether or not the light-emitting element has a defect, according to a measured value of an inter-terminal voltage at a time when the set drive current is injected into the light-emitting element.

In the apparatus for inspecting a light-emitting element according to the fourth aspect of the invention, the drive current setting unit may obtain a current-light output characteristic of the light-emitting element according to an injected current and a measured light output, and may set a drive current using the current-light output characteristic.

In the apparatus for inspecting a light-emitting element according to the fourth aspect of the invention, the drive current setting unit may set a drive current according to a current at which a measured light output is a maximum value.

In the apparatus for inspecting a light-emitting element according to the fourth aspect of the invention, the drive current setting unit may set, as a drive current, a current equal to or larger than a current at which a light output measured by the light output measurement unit is a maximum value and equal to or smaller than a current at which a light output measured by the light output measurement unit is 70% of the maximum value.

According to a fifth aspect of the invention, a burn-in method for eliminating an initial change in light output of a light-emitting element includes (a) measuring a light output of a light-emitting element while injecting a current into the light-emitting element, (b) setting a drive current according to an injected current and a measured light output, and (c) injecting the drive current into the light-emitting element for a predetermined time or longer.

In the light-emitting element burn-in method according to the fifth aspect of the invention, in step (b), a current-light output characteristic of the light-emitting element may be obtained according to an injected current and a measured light output, and a drive current may be set using the current-light output characteristic.

The light-emitting element burn-in method according to the fifth aspect of the invention may further include putting a light-emitting element under a predetermined temperature environment between steps (b) and (c).

In the light-emitting element burn-in method according to the fifth aspect of the invention, in step (b), a drive current may be set according to a current at which a measured light output is a maximum value.

In the light-emitting element burn-in method according to the fifth aspect of the invention, in step (b), a current equal to or larger than a current at which a measured light output is a maximum value and equal to or smaller than a current at which a measured light output is 70% of the maximum value may be set as a drive current.

According to a sixth aspect of the invention, a light-emitting element burn-in apparatus includes a current injection unit for injecting a current into a light-emitting element, a light output measurement unit for measuring a light output of the light-emitting element, a drive current setting unit for setting a drive current according to an injected current and a measured light output, and a drive current injection unit for injecting the drive current into the light-emitting element for a predetermined time or longer.

### BRIEF DESCRIPTION OF THE DRAWINGS

The invention will be described with reference to the accompanying drawings, wherein like numbers reference like elements.

FIG. 1 is a block diagram showing a functional configuration of a light-emitting element inspection apparatus according to a first embodiment of the invention.

FIG. 2 is a sectional view schematically showing a surface-emitting semiconductor laser as an example of the light-emitting element.

FIG. 3 is a flowchart showing a light-emitting element inspection method according to the first embodiment.

FIG. 4 is a graph showing an example of a current-light output characteristic of the surface-emitting semiconductor laser.

FIG. 5 is a graph showing the temperature around the active layer in a case where the surface-emitting semiconductor laser is driven.

FIG. 6 is a graph showing the life of the surface-emitting semiconductor laser in a case where the surface-emitting semiconductor laser is driven under each temperature environment.

FIG. 7 is a graph showing the light output in a case where the surface-emitting semiconductor laser is driven.

FIG. 8 is a graph showing the inter-terminal voltage in a case where the surface-emitting semiconductor laser is driven.

FIG. 9 is a block diagram showing a functional configuration of a burn-in apparatus according to a second embodiment of the invention.

FIG. 10 is a flowchart showing a burn-in method according to the second embodiment.

FIG. 11 is a graph showing changes in light output with time in a case where the surface-emitting semiconductor laser was driven.

### DESCRIPTION OF EXEMPLARY EMBODIMENTS

Embodiments of the invention will now be described with reference to the accompanying drawings.

### 1. Apparatus and Method for Inspecting Light-Emitting Element

### 1.1 First, Components of a Light-Emitting Element According to a First Embodiment of the Invention will be Described

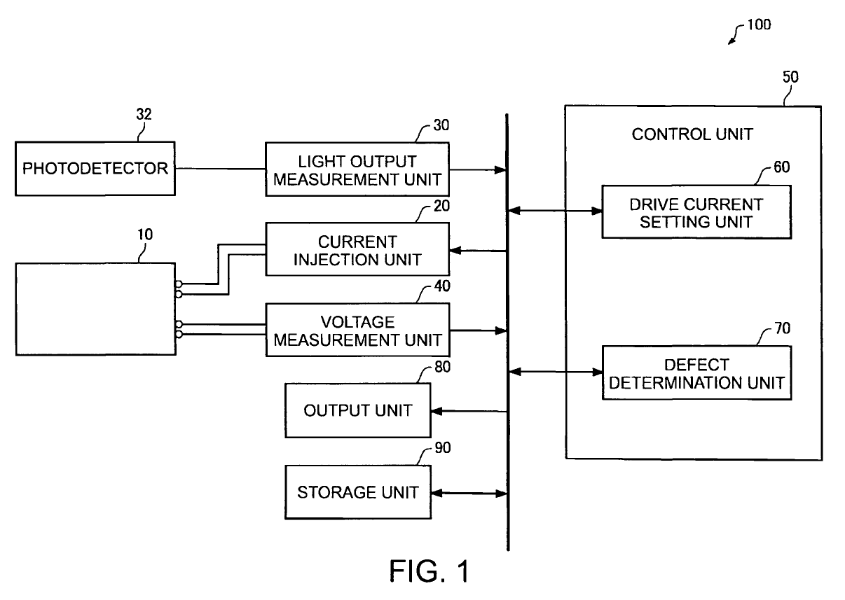

FIG. 1 is a block diagram showing a functional configuration of a light-emitting element inspection apparatus 100 according to this embodiment. Using a light-emitting element 10, the inspection apparatus 100 sets a drive current to be carried to a light-emitting element to be inspected. The inspection apparatus 100 includes a current injection unit 20, a light output measurement unit 30, a photodetector 32, a voltage measurement unit 40, a control unit 50, an output unit 80, and a storage unit 90. The control unit 50 includes a drive current setting unit 60 and a defect determination unit 70.

The current injection unit 20 injects a forward current for driving the light-emitting element 10 into the element. The current injection unit 20 is able to change the magnitude of a current to be injected into the light-emitting element 10. For example, it is able to change the magnitude of a current according to an instruction from the control unit 50.

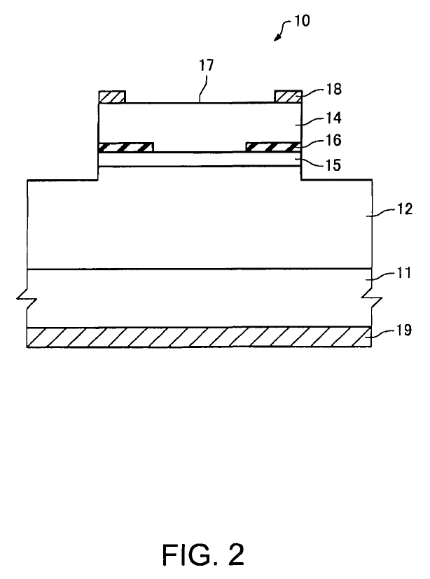

The light-emitting element 10 has no particular limitation with respect to its structure as long as the element is a semiconductor device having a function of emitting light. It may be a surface-emitting semiconductor laser. FIG. 2 is a sectional view schematically showing a surface-emitting semiconductor laser as an example of the light-emitting element 10. The surface-emitting semiconductor laser 10 includes a semiconductor substrate 11, a first mirror 12 formed on the semiconductor substrate 11, an active layer 15 formed on the first mirror 12, and a second mirror 14 formed on the active layer 15. The first and second mirrors 12 and 14 are each formed of a multilayer film including multiple semiconductors having different reflection indexes. For example, these mirrors may be distributed reflection multilayer film mirrors. The surface-emitting semiconductor laser 10 also includes a current narrowing layer 16 formed by oxidizing a side surface of a semiconductor layer of the second mirror 14 near the active layer 15. The first and second mirrors 12 and 14 are doped with impurities so that these mirrors are of different conductivity types, p-type and n-type. For example, the first mirror 12 is made to be of n-type and the second mirror 14 to be of p-type, and the active layer 15 is formed of an intrinsic semiconductor, thereby forming a pin diode resonator.

The surface-emitting semiconductor laser 10 includes a first electrode 18 and a second electrode 19. The first electrode 18 is formed on the upper surface of the second mirror 14, for example, so as to be annular and flat. Light is emitted upward from an aperture of the first electrode 18. The second electrode 19 is formed on the back surface of the semiconductor substrate 11. The surface-emitting semiconductor laser 10 is driven by the first and second electrodes 18 and 19. The light-emitting element 10 is not limited to the above-mentioned surface-emitting semiconductor laser and, for example, may be an external resonator semiconductor laser from which a part of a mirror is separated.

The photodetector 32 has a function of monitoring a light output generated in the light-emitting element 10. Specifically, the photodetector 32 converts light generated in the light-emitting element 10 into a current. The light output generated in the light-emitting element 10 is detected using the value of this current. For example, the photodetector 32 may be a [0]p-intrinsic-n (PIN) photodiode or an avalanche photodiode.

The light output measurement unit 30 measures the light output according to the current converted from the light in the photodetector 32, and then sends information indicating the measured value, to the drive current setting unit 60 or the defect determination unit 70.

The voltage measurement unit 40 measures the inter-terminal voltage of the light-emitting element 10. Specifically, it measures the voltage across the first and second electrodes 18 and 19 of the light-emitting element 10 while the current is injected by the current injection unit 20. The voltage measurement unit 40 sends information indicating the measured inter-terminal voltage, to the detect determination unit 70.

The drive current setting unit 60 sets the amplitude of a drive current for inspecting a light-emitting element according to the value of the current injected into the light-emitting element 10 by the current injection unit 20 and the value of the light output of the light-emitting element 10. Specifically, the drive current setting unit 60 sends information indicating the value of a current that should be injected into the light-emitting element 10, to the current injection unit 20. At that time, the drive current setting unit 60 preferably sends multiple current values, which preferably include current values equal to or larger than a current value that causes the light-emitting element 10 to produce the maximum light output. For example, the light output measurement unit 30 may measure the light output while gradually increasing the value of a current being injected into the light-emitting element 10, and the current injection unit 20 may stop injecting the current once a measured light output value has fallen below the preceding measured value.

Subsequently, the drive current setting unit 60 receives the measured value of the light output from the light output measurement unit 30, and associates the measured value of the light output with the value of the current injected into the light-emitting element 10. The drive current setting unit 60 successively stores the associated light output measured value and current value in the storage unit 90 one after another. If the control unit 50 includes a storage area, the drive current setting unit 60 may store the associated light output measured value and current value in the storage area.

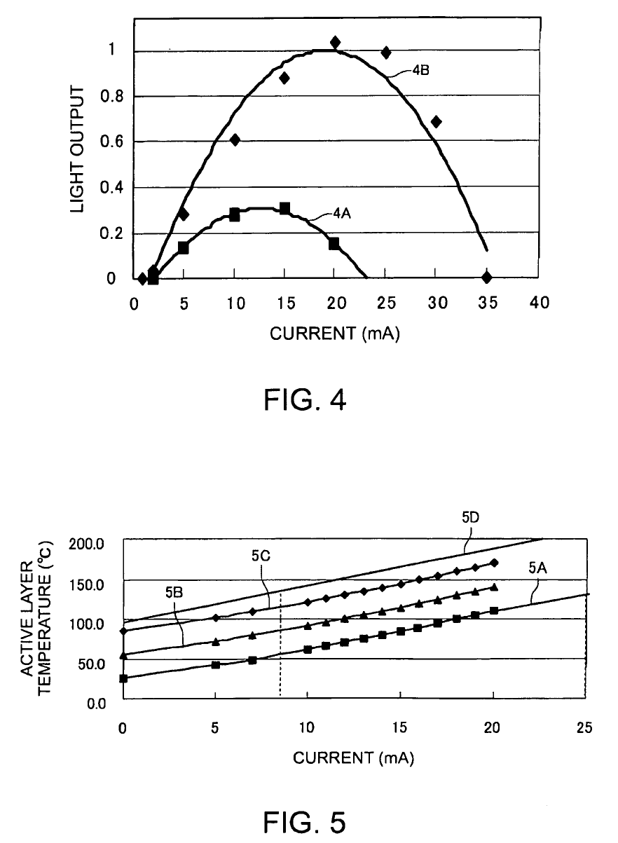

Subsequently, the drive current setting unit 60 obtains a current-light output characteristic according to the stored light output measured values and current values. FIG. 4 is a graph showing an example of a current-light output characteristic according to this embodiment. In FIG. 4, the transverse axis represents the current (mA) and the vertical axis represents the light output. A curve 4A represents a current-light output characteristic in a case where the ambient temperature is 100° C., and a curve 4B represents that in a case where the ambient temperature is 25° C. With regard to the light output, the maximum light output value indicated by the curve 4B is standardized as 1. The curve 4A indicates the maximum light output at a current of 12 mA, and indicates nearly zero light output at a current of 23 mA. The curve 4B indicates the maximum light output at a current of 20 mA, and indicates nearly zero light output at a current of 35 mA. That is, once the current value has exceeded a certain value, the light output is reduced even if the current is further increased.

The drive current setting unit 60 sets a drive current according to a current at which the curve A or curve B described above indicates the maximum light output. More specifically, the drive current setting unit 60 sets, as a drive current, a current that is larger than a current at which the light output is the maximum and smaller than a current at which the light output indicates 70% of the maximum light output. The curve 4A shows the maximum light output at a current of 12 mA and 70% of the maximum light output at a current of 18 mA. Therefore, the drive current setting unit 60 sets any value between 12 mA and 18 mA, for example, 13 mA, as a drive current. The curve 4B shows the maximum light output at a current of 20 mA and 70% of the maximum light output at a current of 28 mA. Therefore, the drive current setting unit 60 sets any value between 20 mA and 28 mA, for example, 25 mA, as a drive current.

The drive current setting unit 60 sends information indicating the set drive current to the current injection unit 20 so that the current injection unit 20 injects the set drive current into the light-emitting element 10. The drive current setting unit 60 may also send information indicating the set drive current or the current-light output characteristic, to the output unit 80.

The defect determination unit 70 receives light outputs obtained when the drive current is continuously injected into the light-emitting element 10, from the light output measurement unit 30 and determines whether or not the light-emitting element 10 has a defect, according to the received light outputs. Specifically, the defect determination unit 70 receives the initial value of the light output and a light output obtained after the lapse of a predetermined time from start of injection of the drive current, at least from the light output measurement unit 30. If the rate of change of the light output obtained after the lapse of the predetermined time with respect to the initial light output value is equal to or larger than a predetermined value, the defect determination unit 70 determines that the light-emitting element 10 has a defect, and then sends information to this effect to the output unit 80.

Also, the defect determination unit 70 may receive the inter-terminal voltage (voltage between the anode and the cathode) of the light-emitting element 10 obtained when the drive current is continuously injected into the light-emitting element 10, from the voltage measurement unit 40 to determine whether the light-emitting element 10 has a defect, according to the received inter-terminal voltage. Specifically, the defect determination unit 70 receives the initial value of the inter-terminal voltage and an inter-terminal voltage obtained after the lapse of a predetermined time from start of injection of the drive circuit, at least from the voltage measurement unit 40. If the rate of change of the inter-terminal voltage obtained after the lapse of the predetermined time with respect to the initial inter-terminal voltage value is equal to or larger than a predetermined value, the defect determination unit 70 determines that the light-emitting element 10 has a defect, and then sends information to this effect to the output unit 80.

Further, the defect determination unit 70 may determine whether or not the light-emitting element 10 has a defect, according to both the light output and the inter-terminal voltage obtained when the drive current is continuously injected into the light-emitting element 10. In this case, if the rate of change of any one of the light output and the inter-terminal voltage with respect to its initial value is equal to or larger than the predetermined value, the defect determination unit 70 may determine that the light-emitting element 10 has a defect. Or, if the rates of change of both the light output and the inter-terminal voltage with respect to the respective initial values are equal to or larger than the respective predetermined values, the defect determination unit 70 may determine that the light-emitting element 10 has a defect.

According to the inspection apparatus 100 according to this embodiment, the drive current set according to the current-light output characteristic of the light-emitting element is injected into the light-emitting element 10. This allows growth and proliferation of a possible defect included in the light-emitting element 10 at an accelerated speed. Such growth and proliferation of the defect appears in the form of changes in light output and/or inter-terminal voltage. This allows the defect to be found in the inspection stage. It is conceivable that such growth and proliferation of the defect is promoted at an accelerated speed by a synergy effect between an effect caused by an increase in temperature around the active layer of the light-emitting element 10 and an effect of a current that is not used to oscillate a laser.

In this embodiment, the drive current to be used for inspection is preferably equal to or larger than a current at which the light output is the maximum. This is because if the drive current falls below the current at which the light output is the maximum, most of the injected current will be used to oscillate a laser, whereby the defect included in the light-emitting element 10 will not be sufficiently grown within the inspection time. Thus, according to the inspection method according to this embodiment, the ability to detect a possible defect in a light-emitting element is significantly improved.

Also, in this embodiment, the drive current to be used for inspection is preferably equal to or smaller than a current at which the light output is 70% of the maximum. This is because if a drive current exceeding the current at which the light output is 70% of the maximum is injected, most of the injected current will be used for a purpose other than oscillating a laser. This may cause an additional defect, resulting in a reduction in life of the light-emitting element rather than increasing the life.

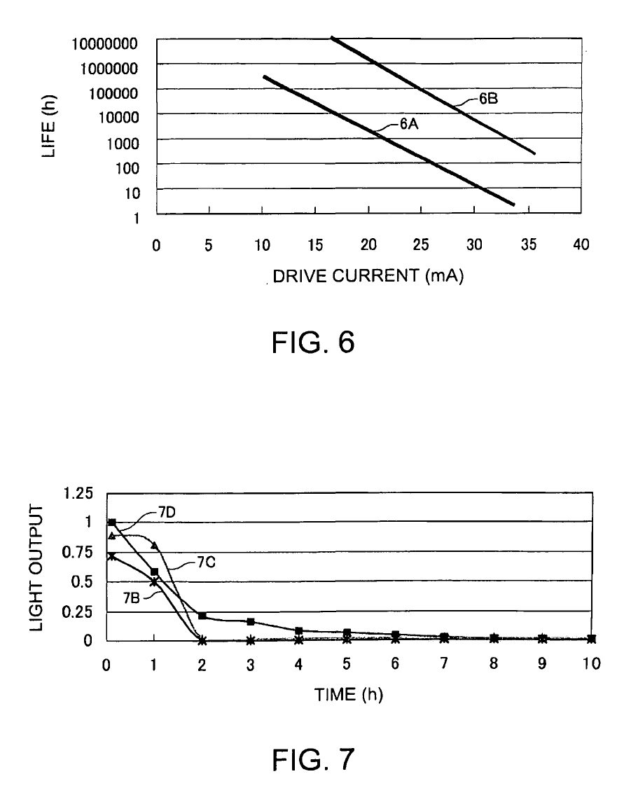

The light-emitting element 10 is preferably put under a room temperature environment. For example, the room temperature is preferably 10 to 40° C. Conducting an inspection under such a room temperature environment eliminates the need to use temperature-controlled equipment such as a temperature-controlled bath. Thus, this inspection apparatus serves as environmentally friendly equipment that saves energy and reduces carbon dioxide emissions. Also, this inspection apparatus reduces the equipment cost. Inspecting the light-emitting element 10 under such an environment prevents a reduction in life of the light-emitting element 10 due to undergoing an inspection, compared with inspecting it at a higher temperature. The relation between the ambient temperature and the life will be described with reference to FIGS. 5 and 6.

FIG. 5 is a graph showing the temperature around the active layer in a case where a current is injected into the surface-emitting semiconductor laser under each temperature environment. In FIG. 5, the transverse axis represents the current injected into the surface-emitting semiconductor laser, and the vertical axis represents the temperature around the active layer. A curve 5A indicates changes in temperature around the active layer at an ambient temperature of 25° C., a curve 5B indicates those at an ambient temperature of 50° C., a curve 5C indicates those at an ambient temperature of 80° C., and a curve 5D indicates those at an ambient temperature of 100° C.

While the temperature around the active layer is increased by increasing the ambient temperature, it is also increased by increasing the value of the current to be injected. From to FIG. 5, it its understood that even if the ambient temperature is low as indicated by the curve 5A, the temperature around the active layer is increased by increasing the value of the current being injected. Specifically, it is understood from the curves 5A and 5D that the temperature around the active layer in a case where a current of 25 mA is injected into the surface-emitting semiconductor laser under a 25° C. temperature environment is approximately the same as that in a case where a current of 8 mA is injected into the surface-emitting semiconductor laser under a 100° C. temperature environment. Thus, even if the ambient temperature is low, the temperature around the active layer is increased by adjusting the drive current.

Effects that the drive current and the ambient temperature have on the life of the surface-emitting semiconductor laser will now be described.

FIG. 6 is a graph showing the life of the surface-emitting semiconductor laser in a case where a current is injected into the semiconductor laser under each temperature environment. In FIG. 6, the transverse axis represents the drive current injected into the surface-emitting semiconductor laser and the vertical axis represents the life of surface-emitting semiconductor laser. A curve 6A indicates the life at a 100° C. ambient temperature and a curve 6B indicates the life at a 25° C. ambient temperature. From to FIG. 6, it is understood that if the drive current is the same, the life at a 25° C. ambient temperature is 1000 times that at a 100° C. ambient temperature. Therefore, it is preferable to inspect the light-emitting element 10 at a lower temperature. For example, the curve 6A indicates the life of approximately 100 hours at a drive current of 25 mA. If the inspection time is 20 hours, 20% of the life of the surface-emitting semiconductor laser will be used for the inspection. On the other hand, the curve 6B indicates the life of approximately 100,000 hours at a drive current of 25 mA. If the inspection time is 20 hours, only 0.02% of the life thereof will be used for the inspection. Thus, the ratio of the inspection time to the life is substantially reduced by lowering the ambient temperature.

### 1.2 Next, A Method for Inspecting the Light-Emitting Element 10 According to this Embodiment will be Described in the Order of Steps.

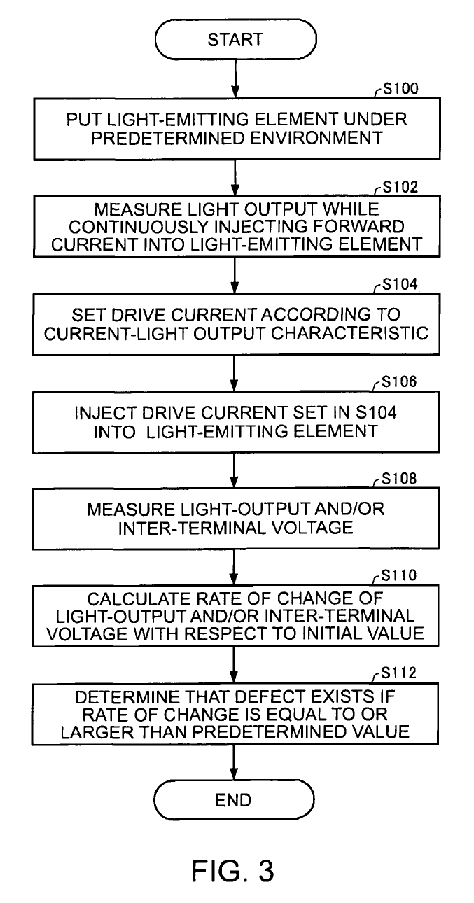

FIG. 3 is a flowchart showing the method for inspecting the light-emitting element 10 according to this embodiment.

First, the light-emitting element 10 is put under a predetermined temperature environment (step S100). The predetermined temperature is preferably the room temperature, for example, 10 to 40° C. It is sufficient that the room temperature is a temperature for which no temperature-controlled equipment need be used. Multiple light-emitting elements may be put under the predetermine temperature environment and then subjected to the following steps.

Next, the inspection apparatus 100 measures a light output of the light-emitting element 10 while injecting a forward current to the element (step S102).

Next, the inspection apparatus 100 sets a drive current according to a current-light output characteristic (step S104). The drive current set here is preferably larger than a current at which the light output is the maximum and smaller than a current at which the light output is 70% of the maximum light output.

Next, the drive current set in the above-mentioned step S104 is injected into the light-emitting element 10 (step S106). The time during which the drive current is injected may be a predetermined time or a time taken until changes in light output or inter-terminal voltage to be discussed later fall below a predetermined value.

Next, the light output or inter-terminal voltage at the time when the drive current is injected into the light-emitting element 10 is measured (step S108). The measurement is made while injecting the drive current into the light-emitting element 10.

Next, the rate of change of the light output or inter-terminal voltage measured after the lapse of a predetermined time with respect to the initial measured value is calculated (step S110). The rate of change may be calculated with respect to both the light output and inter-terminal voltage.

If the calculated rate of change is equal to or larger than a predetermined value, it is determined that the light-emitting element 10 has a defect (step S112). Here, it can be determined that an included defect has further grown or proliferated as the rate of change of the light output or inter-terminal voltage is high.

### 1.3 Experimental Example

A verification experiment to be discussed below was conducted with respect to the inspection method according to this embodiment.

First, a current-light output characteristic of the surface-emitting semiconductor laser was created. The created current-light output characteristic is represented by the curve 4B of FIG. 4. The drive current was set to 25 mA according to the curve 4B.

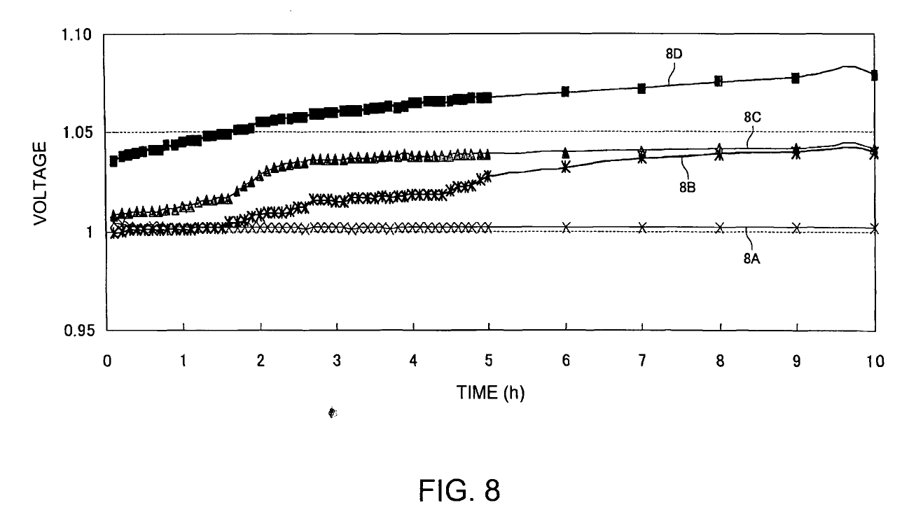

Three surface-emitting semiconductor lasers that were subjected to electrical stress caused by static electricity so as to generate a defect therein were prepared as samples. The light output and inter-terminal voltage were measured while injecting a drive current of 25 mA into each sample under a 25° C. temperature environment. The measurement results are shown in FIGS. 7 and 8.

FIG. 7 is a graph showing the light output measured when the drive current was injected into each surface-emitting semiconductor laser. In FIG. 7, the transverse axis represents the time during which the drive current is injected and the vertical axis represents the light output. With regard to the light output, the initial value of a curve 7D is standardized as 1. Curves 7B and 7C and the curve 7D indicate the light outputs of the surface-emitting semiconductor lasers subjected to electrical stress.

For the curve 7B, the light output was initially approximately 0.75, but gradually decreased and became 0 two hours later. For the curve 7C, the light output was initially approximately 0.9, but gradually decreased and became 0 two hours later. For the curve 7D, the light output was initially approximately 1.0, but gradually decreased and became 0.2 two hours later, and thereafter further decreased and became 0 seven hours later. That is, all the samples no longer emitted light two hours later or seven hours later.

From FIG. 7, it is confirmed that the characteristic of each sample was degraded in a short time by injecting, thereinto, a current of 25 mA that is the drive current set according to the current-light output characteristic. It is conceivable that the promotion of growth and proliferation of a defect included in each sample caused such degradation in a short time.

FIG. 8 is a graph showing the inter-terminal voltage at the time when the drive current is injected into each surface-emitting semiconductor laser. In FIG. 8, the transverse axis represents the time during which the drive current is injected and the vertical axis represents the inter-terminal voltage. With regard to the inter-terminal voltage, the initial value of a curve 8A is standardized as 1. The curve 8A indicates the inter-terminal voltage of a surface-emitting semiconductor laser not subjected to electrical stress that was prepared as a comparative sample, and curves 8B, 8C, and 8D indicate the inter-terminal voltages of the above-mentioned sample surface-emitting semiconductor lasers subjected to electrical stress.

For the curve 8A, the inter-terminal voltage was approximately the same as the initial value thereof even ten hours later. For the curve 8B, the inter-terminal voltage was initially approximately 1.0, but increased gradually and become 1.04 ten hours later. For the curve 8C, the inter-terminal voltage was initially approximately 1.01, but increased gradually and became 1.04 ten hours later. For the curve 8D, the inter-terminal voltage was initially approximately 1.03, but increased gradually and became 1.08 ten hours later.

From FIG. 8, it is confirmed that the characteristics of the samples subjected to electrical stress were degraded in a short time by injecting, thereinto, a current of 25 mA that is the drive current set according to the current-light output characteristic. It is conceivable that the promotion of growth and proliferation of defects included in these samples caused such degradation in a short time.

From the above-mentioned experimental results, it is confirmed that a proper drive current is set by applying the inspection method according to this embodiment and that it is determined whether a light-emitting element has a defect, from the light output or inter-terminal voltage measured when the drive current is injected.

This completes the description of the apparatus and method for inspecting a light-emitting element according to this embodiment. In this embodiment, an inspection is conducted with respect to a single light-emitting element; however, with being limited to this, multiple light-emitting elements may be inspected simultaneously. Also, one of light-emitting elements in a production lot may be used to determine the drive current, and the presence/non-presence of a defect may be determined with respect to multiple light-emitting elements in the same production lot.

Apparatus and Method for Burning in Light-Emitting Element

### 2.1 Next, Components of a Burn-In Apparatus According to a Second Embodiment of the Invention will be Described

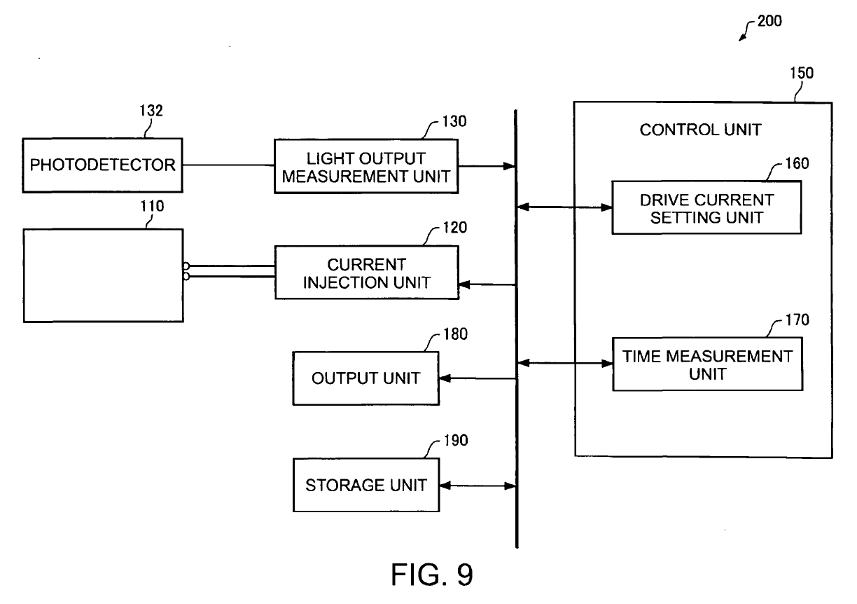

FIG. 9 is a block diagram showing a functional configuration of a light-emitting element burn-in apparatus 200 according to this embodiment. The burn-in apparatus 200 has a function of eliminating initial changes in characteristic of a light-emitting element 110 by driving the element for a predetermined time. The burn-in apparatus 200 includes a current injection unit 120, a light output measurement unit 130, a photodetector 132, a control unit 150, an output unit 180, and a storage unit 190. The control unit 150 includes a drive current setting unit 160 and a time measurement unit 170.

The current injection unit 120 injects a forward current for driving the light-emitting element 110 into the element. The current injection unit 120 is able to change the magnitude of a current to be injected into the light-emitting element 110. For example, it is able to change the magnitude of a current according to an instruction from the control unit 150.

The light-emitting element 110 has no limitation with respect to its structure as long as it is a semiconductor device having a function of emitting light. It may be a surface-emitting semiconductor laser. Surface-emitting semiconductor lasers include what is shown as an example of the light-emitting element 10 in FIG. 2.

The photodetector 132 has a function of monitoring the light output generated in the light-emitting element 110. Specifically, the photodetector 132 converts light generated in the light-emitting element 110 into a current. The light output generated in the light-emitting element 110 is detected using the value of this current. For example, the photodetector 132 may be a [0]PIN photodiode or an avalanche photodiode.

The light output measurement unit 130 measures the light output according to the current converted from the light in the photodetector 132, and then sends information indicating the measured value, to the drive current setting unit 160.

The drive current setting unit 160 determines the amplitude of a drive current for inspecting a light-emitting element according to the value of the current injected into the light-emitting element 110 by the current injection unit 120 and the value of the light output of the light-emitting element 110. Specifically, the drive current setting unit 160 sends information indicating the value of a current that should be injected into the light-emitting element 110, to the current injection unit 120. At that time, the drive current setting unit 160 preferably sends multiple current values, which preferably include current values larger than a current value that causes the light-emitting element 110 to produce the maximum light output. For example, the light output measurement unit 130 may measure the light output while gradually increasing the value of the current being injected into the light-emitting element 110, and the current injection unit 120 may stop injecting the current once a measured light output value has fallen below the preceding measured value.

Subsequently, the drive current setting unit 160 receives a measured light output value from the light output measurement unit 130, and associates the measured light output value with a value of the current injected into the light-emitting element 110. The drive current setting unit 160 stores the associated measured light output value and current value in the storage unit 90 one after another. If the control unit 150 includes a storage area, the drive current setting unit 160 may store the associated measured light output value and current value in the storage area.

Subsequently, the drive current setting unit 160 obtains a current-light output characteristic according to the stored measured light output values and current values. An example of such a current-light output characteristic is as shown in FIG. 4. FIG. 4 has been described above.

The drive current setting unit 160 sets a drive current according to a current at which the light output is the maximum in the curve A or curve B in FIG. 4. More specifically, it sets, as a drive current, a current larger than a current at which the light output is the maximum and the current smaller than a current at which the light output is 70% of the maximum. The curve 4A shows the maximum light output at a current of 12 mA. Therefore, the drive current setting unit 160 sets any current value that is 12 mA or larger, for example, 13 mA, as a drive current. The curve 4B shows the maximum light output at a current of 20 mA and 70% of the maximum light output at a current of 28 mA. Therefore, the drive current setting unit 160 sets any current value that is from 20 mA to 28 mA, for example, 25 mA, as a drive current.

The drive current setting unit 160 sends information indicating the set drive current to the current injection unit 120 so that the current injection unit 120 injects the drive current into the light-emitting element. The drive current setting unit 160 may also send information indicating the set drive current or the current-light output characteristic, to the output unit 180.

The drive current setting unit 160 may cause the current injection unit 120 to inject the drive current into a different light-emitting element as long as the different light-emitting element is included in the same production lot as the light-emitting element 110 used to determine the drive current.

The time measurement unit 170 determines whether or not the time during which the current injection unit 120 has injected the drive current into the light emitting element has reached a predetermined time. If the time measurement unit 170 determines that the predetermined time has been reached, it sends an instruction for stopping injecting the drive current to the current injection unit 120. For example, the time measurement unit 170 may send such an instruction to the current injection unit 120 after the lapse of 24 hours from start of the injection. Also, the time measurement unit 170 may receive light output values from the light output measurement unit 130 during injection of the drive current, and once it has determined that the rate of change of the light output per hour has fallen within a predetermined value, it may send such an instruction to the current injection unit 120.

According to the burn-in apparatus 200 according to this embodiment, the drive current set according to the current-light output characteristic of the light-emitting element 110 is injected into the element. As a result, initial changes in characteristic of the light emitting element 110 are eliminated in a short time so that the characteristic is stabilized.

The light-emitting element 110 is preferably put under a room temperature environment. For example, the room temperature is preferably 10 to 40° C. Performing burn-in under such a room temperature environment eliminates the need to use temperature-controlled equipment such as a temperature-controlled bath, resulting in a reduction in cost. Also, burning in the light-emitting element 110 under such an environment prevents a reduction in life of the light-emitting element 110 due to undergoing burn-in, compared with burning in it at a higher temperature.

### 2.2 Next, A Burn-In Method According to this Embodiment will be Described in the Order of Steps

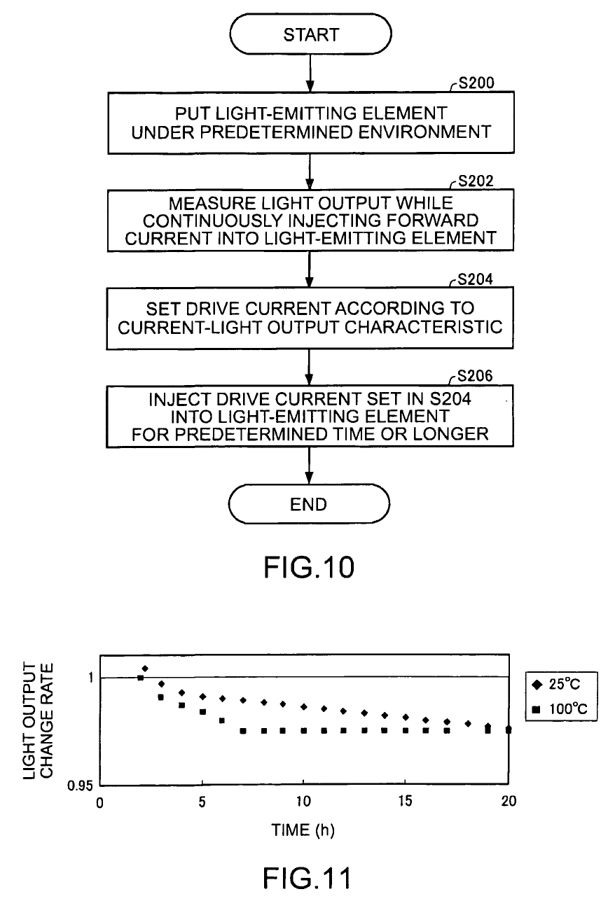

FIG. 10 is a flowchart showing the burn-in method according to this embodiment.

First, the light-emitting element 110 and multiple light-emitting elements included in the same production lot as the light-emitting element 110 are put under a predetermined temperature environment (step S200). The predetermined temperature is preferably the room temperature, for example, 10 to 40° C. It is sufficient that the room temperature is a temperature for which no temperature-controlled equipment need be used.

Next, the burn-in apparatus 200 measures a light output of the light-emitting element 110 while injecting a forward current into the element (step S202).

Next, the burn-in apparatus 200 sets the drive current according to the current-light output characteristic (step S204). The drive current set here is preferably equal to or larger than a current at which a measured light output is a maximum value and equal to or a smaller than a current at which a measured light output is 70% of the maximum value.

Next, the drive current set in the above-mentioned step S204 is injected into the light-emitting element (step S206). For example, the time during which the drive current is injected may be 24 hours.

### 2.3 Experimental Example

A verification experiment to be discussed below was conducted with respect to the burn-in method according to the second embodiment.

The rate of change of the light output was measured while burning in (injecting the drive current into) a surface-emitting semiconductor laser. The measurement was made with respect to both a case where the surface-emitting semiconductor laser is put under a 25° C. temperature environment and a case where it is put under a 100° C. temperature environment.

FIG. 11 is a graph showing changes in light output with time in a case where the surface-emitting semiconductor laser was driven by the drive current according to the second embodiment. In FIG. 11, the transverse axis represents the time during which the drive current is injected and the vertical axis represents the rate of change of the light output with respect to the initial value.

From FIG. 11, it is confirmed that injection of the drive current according to the second embodiment eliminated initial changes in characteristic of the surface-emitting semiconductor laser in a short time so as to stabilize the characteristic.

Also, from FIG. 11, it is understood that the rate of change in the case where the surface-emitting semiconductor laser was put under a 100° C. temperature environment became constant earlier than that in the case where the surface-emitting semiconductor laser is put under a 25° C. temperature environment. However, even under the 25° C. temperature environment, the rate of change became constant 20 hours later. That is, it is confirmed that selecting the drive current and conducting the test for approximately one day eliminated initial changes even under the room temperature environment so as to stabilize the characteristic. With regard to the relation between the ambient temperature and the life of the light-emitting element, the ratio of the inspection time to the life is significantly reduced by lowering the ambient temperature, as described in 1.1 with reference to FIG. 6. Therefore, it is preferable that the ambient temperature be set as appropriate in consideration of the life and production cycle time of the light-emitting element.

This completes the description of the apparatus and method for burn-in according to the second embodiment.

The embodiments of the invention have been described in detail. It will easily be understood by those skilled in the art that various modifications can be made thereto without substantially departing from the novel features and advantages of the invention. Accordingly, such modifications will fall within the scope of the invention.

What is claimed is:

1. A method for inspecting a light-emitting element for a defect, comprising:
(a) measuring a light output of a light-emitting element while injecting a current into the light-emitting element;
(b) setting a drive current according to an injected current and a measured light output;
(c) measuring a light output while injecting the set drive current into the light-emitting element in a forward direction; and
(d) determining whether or not the light-emitting element has a defect, according to the light output measured in step (c).

2. The method for inspecting a light-emitting element according to claim 1, wherein,
in step (b), a current-light output characteristic of the light-emitting element is obtained according to an injected current and a measured light output, and a drive current is set using the current-light output characteristic.

3. The method for inspecting a light-emitting element according to claim 1, further comprising
putting a light-emitting element under a predetermined temperature environment prior to step (a).

4. The method for inspecting a light-emitting element according to claim 3, wherein
the predetermined temperature is a room temperature.

5. The method for inspecting a light-emitting element according to claim 1, wherein
in step (b), a current equal to or larger than a current at which a measured light output is a maximum value and equal to or smaller than a current at which a measured light output is 70% of the maximum value is set as a drive current.

6. The method for inspecting a light-emitting element according to claim 1, wherein
in step (c), at least an initial value of the light output and a light output after a lapse of a predetermined time from start of injection of the drive current are measured, and
in step (d), if a rate of change of the light output after the lapse of the predetermined time with respect to the initial value is equal to or larger than a predetermined value, it is determined that the light-emitting element has a defect.

7. A method for inspecting a light-emitting element for a defect, comprising:
(a) measuring a light output of a light-emitting element while injecting a current into the light-emitting element;
(b) setting a drive current according to an injected current and a measured light output;
(c) measuring an inter-terminal voltage while injecting the set drive current into the light-emitting element in a forward direction; and
(d) determining whether or not the light-emitting element has a defect, according to the inter-terminal voltage.

8. The method for inspecting a light-emitting element according to claim 7, wherein,
in step (c), at least an initial value of the inter-terminal voltage and an inter-terminal voltage after a lapse of a predetermined time from start of injection of the drive current are measured, and
in step (d), if a rate of change of the inter-terminal voltage after the lapse of the predetermined time with respect to the initial value is equal to or larger than a predetermined value, it is determined that the light-emitting element has a defect.

9. An inspection apparatus for inspecting a light-emitting element for a defect, comprising:
a current injection unit for injecting a current into a light-emitting element;
a light output measurement unit for measuring a light output of the light-emitting element; and
a drive current setting unit for setting a drive current according to an injected current and a measured light output; and
a defect determination unit for determining whether or not the light-emitting element has a defect, according to a measured value of a light output at a time when the set drive current is injected into the light-emitting element.

10. The apparatus for inspecting a light-emitting element according to claim 9, wherein
the drive current setting unit obtains a current-light output characteristic of the light-emitting element according to an injected current and a measured light output, and sets a drive current using the current-light output characteristic.

11. The apparatus for inspecting a light-emitting element according to claim 9, wherein
the drive current setting unit sets, as a drive current, a current equal to or larger than a current at which a light output measured by the light output measurement unit is a maximum value and equal to or smaller than a current at which a light output measured by the light output measurement unit is 70% of the maximum value.

12. An inspection apparatus for inspecting a light-emitting element for a defect, comprising:
a current injection unit for injecting a current into a light-emitting element;
a light output measurement unit for measuring a light output of the light-emitting element; and
a drive current setting unit for setting a drive current according to an injected current and a measured light output; and
a defect determination unit for determining whether or not the light-emitting element has a defect, according to a measured value of an inter-terminal voltage at a time when the set drive current is injected into the light-emitting element.

13. The apparatus for inspecting a light-emitting element according to claim 12, wherein
the drive current setting unit obtains a current-light output characteristic of the light-emitting element according to an injected current and a measured light output, and sets a drive current using the current-light output characteristic.

14. The apparatus for inspecting a light-emitting element according to claim 12, wherein
the drive current setting unit sets, as a drive current, a current equal to or larger than a current at which a light output measured by the light output measurement unit is a maximum value and equal to or smaller than a current at which a light output measured by the light output measurement unit is 70% of the maximum value.

15. A burn-in method for eliminating an initial change in light output of a light-emitting element, comprising:
(a) measuring a light output of a light-emitting element while injecting a current into the light-emitting element;
(b) setting a drive current according to an injected current and a measured light output; and
(c) injecting the drive current into the light-emitting element for a predetermined time or longer.

16. The burn-in method according to claim 15, wherein,
in step (b), a current-light output characteristic of the light-emitting element is obtained according to an injected current and a measured light output, and a drive current is set using the current-light output characteristic.

17. The burn-in method according to claim 15, further comprising
putting a light-emitting element under a predetermined temperature environment prior to step (a).

18. The burn-in method according to claim 15, wherein,
in step (b), a current equal to or larger than a current at which a measured light output is a maximum value and equal to or smaller than a current at which a measured light output is 70% of the maximum value is set as a drive current.

19. A burn-in apparatus for eliminating an initial change in light output of a light-emitting element, comprising:
a current injection unit for injecting a current into a light-emitting element;
a light output measurement unit for measuring a light output of the light-emitting element;
a drive current setting unit for setting a drive current according to an injected current and a measured light output; and
a drive current injection unit for injecting the drive current into the light-emitting element for a predetermined time or longer.
